(19) United States
(12) Patent Application Publication
(10) Pub. No.: US 2014/0182663 A1
(43) Pub. Date: Jul. 3, 2014

(54) PHOTOVOLTAIC PANEL SYSTEM, PHOTOVOLTAIC PANEL FASTENING DEVICE, AND METHOD OF INSTALLING PHOTOVOLTAIC PANEL SYSTEM

(71) Applicant: AU Optronics Corporation, Hsin-chu (TW)

(72) Inventors: Min-Chien KUO, HSIN-CHU (TW); Chia-Wen TSAI, HSIN-CHU (TW); Hao-Hung KUAN, HSIN-CHU (TW)

(73) Assignee: AU Optronics Corporation, Hsin-Chu (TW)

(21) Appl. No.: 14/092,661

(22) Filed: Nov. 27, 2013

(30) Foreign Application Priority Data
Dec. 28, 2012 (CN) 201210587393.1

(51) Int. Cl. H01L 31/042

(52) U.S. Cl. CPC H01L 31/0422
USPC 136/251; 248/309.1

(57) ABSTRACT

A photovoltaic panel fastening device includes a loading pedestal, a first supporting plate and a second supporting plate. The loading pedestal includes a plurality of side plates and a bottom plate. The side plates are respectively connected to two opposite sides above the bottom plate, and construct a loading recess. The side plates respectively include an opening. The first supporting plate is connected underneath the bottom plate. The second supporting plate is connected underneath the bottom plate and is connected to one of the side plates.

### RELATED APPLICATIONS

This application claims priority to China Application Serial Number 201210587393.1, filed Dec. 28, 2012, which is herein incorporated by reference.

### BACKGROUND

1. Technical Field

Embodiments of the present invention relate to a photovoltaic device, and particularly relate to a photovoltaic panel system, photovoltaic panel fastening device and a method of installing the photovoltaic panel system.

2. Description of Related Art

Since petroleum stocks are decreasing year by year, currently an energy crisis has become a common concern around the world and the development of alternative energy is urgently required. Among numerous alternative energies, solar energy has an advantage of being inexhaustible, which makes it a focus of the most attention.

Currently, a method of collecting the solar energy is implemented via a photovoltaic panel. The photovoltaic panel is usually installed above a building roof in order to receive a plenty of sunshine for generating sufficient solar energy. During the installation of the photovoltaic panel, an installer installs plural L-shaped supports on the roof, and then mounts the photovoltaic panel on these L-shaped supports.

However, due to the insufficient structural strength of these L-shaped supports, these supports may be deformed upon longtime use or snow accumulation on the photovoltaic panel, which may results in the shift, looseness, or even damage of the photovoltaic panel.

### SUMMARY

In this regard, embodiments of the present invention provide a photovoltaic panel fastening device with high structural strength, in order to solve the issue of insufficient structural strength encountered in the prior art.

According to an embodiment of the present invention, a photovoltaic panel fastening device may include a loading pedestal, a first supporting plate, and a second supporting plate. The loading pedestal may include a plurality of side plates and a bottom plate. These side plates are respectively connected to two opposite sides of the bottom plate, and construct a loading recess. The side plates respectively include a hole. The first supporting plate is connected underneath the bottom plate. The second supporting plate is connected underneath the bottom plate and is connected to one of these side plates.

According to another embodiment of the present invention, a photovoltaic panel system includes a photovoltaic panel, a frame, at least one photovoltaic panel supporting post, and at least one photovoltaic panel fastening device described above. The frame is used to contain the photovoltaic panel. The photovoltaic panel supporting post is fixed on the photovoltaic panel fastening device, and the frame is fixed on the photovoltaic panel supporting post.

According to yet another embodiment of the present invention, a method of installing a photovoltaic panel system includes these steps: providing at least one template; setting a plurality of limit grids on the template; disposing at least one photovoltaic panel fastening device into one of those limit grids, wherein a first fixed foot and a second fixed foot of the photovoltaic panel fastening device under the limit grids are set on the template; fixing a photovoltaic panel on the photovoltaic panel fastening device; and introducing an uncoagulated construction material into the limit grids to cover the first fixed foot and the second fixed foot of the photovoltaic panel fastening device.

In the above embodiments, since the first supporting plate and the second supporting plate are separately positioned to support the loading pedestal from different positions, the structural strength of the photovoltaic panel fastening device can be improved to avoid bending or breaking.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a perspective view of a combination of a photovoltaic panel fastening device and a photovoltaic panel supporting post in accordance with an embodiment of the present invention;

FIG. 2 is a perspective view of the photovoltaic panel fastening device of FIG. 1;

FIG. 3 is a front view of the photovoltaic panel fastening device of FIG. 2;

FIG. 4 is a cross-sectional view of the photovoltaic panel fastening device of FIG. 3 fixed on an architectural structure;

FIG. 5 is a perspective view of a photovoltaic panel system in accordance with an embodiment of the present invention;

FIG. 6A is a cross-sectional view cut along a line C-C′ in FIG. 5;

FIG. 6B is a local cross-sectional view of the photovoltaic panel system in accordance with a variation of the present invention;

FIG. 6C is a local cross-sectional view of the photovoltaic panel system in accordance with another variation of the present invention;

FIG. 6D is a local cross-sectional view of the photovoltaic panel system in accordance with yet another variation of the present invention;

FIGS. 7A-7E respectively are perspective views of steps of installing a photovoltaic panel system in accordance with an embodiment of the present invention;

FIG. 8 is a side view of a photovoltaic panel fastening device on a template in accordance with an embodiment of the present invention; and

FIG. 9 is a side view of a photovoltaic panel fastening device on a template in accordance with another embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

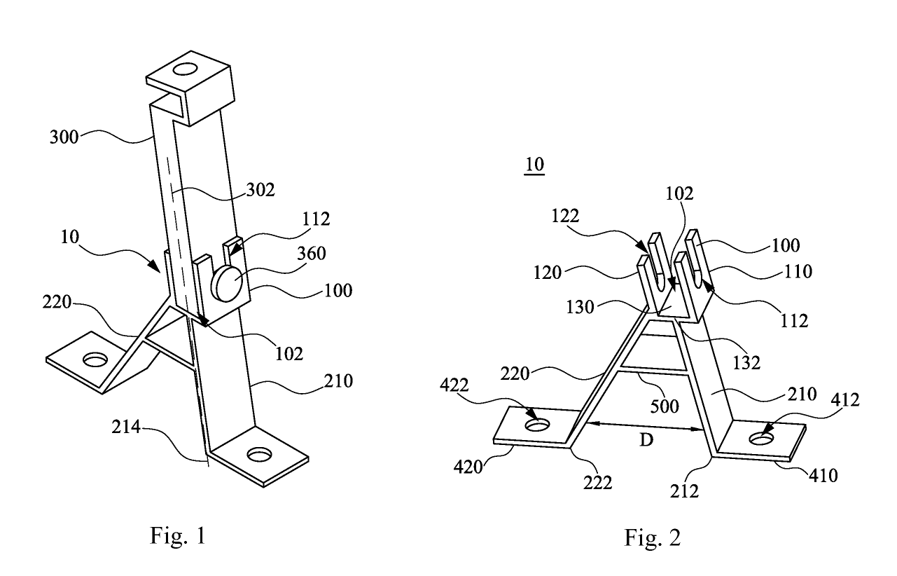

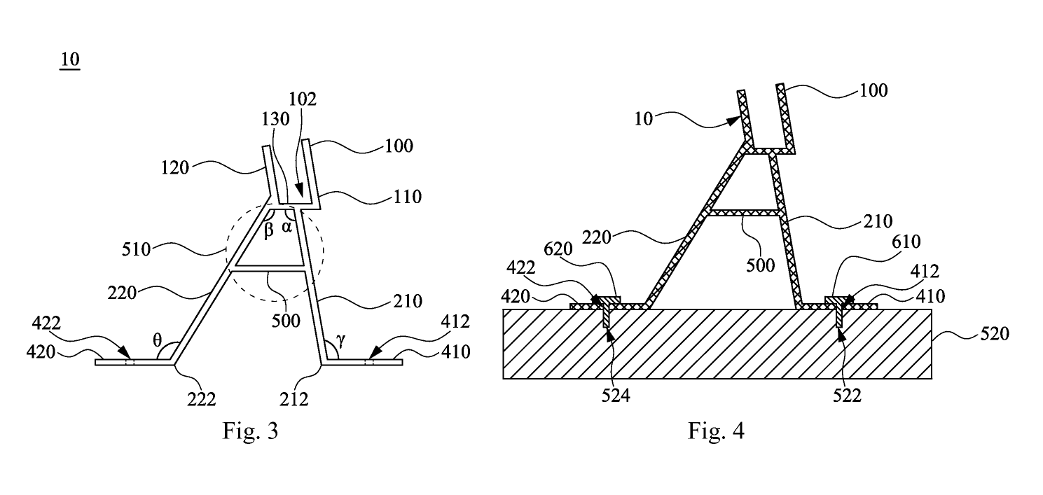

FIG. 1 is a perspective view of a combination of a photovoltaic panel fastening device 10 and a photovoltaic panel supporting post 300 in accordance with an embodiment of the present invention. FIG. 2 is a perspective view of the photovoltaic panel fastening device 10 of FIG. 1. As illustrated in FIGS. 1 and 2, the photovoltaic panel fastening device 10 in this embodiment may include a loading pedestal 100, a first supporting plate 210, and a second supporting plate 220. The loading pedestal 100 may include a side plate 110, a side plate 120, and a bottom plate 130. The side plate 110 and the side plate 120 are disposed on the bottom plate 130 and respectively connected to two opposite ends of the bottom plate 130, and thereby construct a loading recess 102. The first supporting plate 210 is connected underneath the bottom plate 130, and is not contact with the side plate 110 and the side plate 120. The second supporting plate 220 is connected underneath the bottom plate 130, and is connected to the side plate 120. The photovoltaic panel supporting post 300 is abutted the side plate 110, the side plate 120, and the bottom plate 130, and thereby is carried within the loading recess 102.

Since the first supporting plate 210 and the second supporting plate 220 may be respectively connected to the loading pedestal 100 at different positions, the structural strength of the photovoltaic panel fastening device 10 is improved to avoid bending, deformation or breaking of the photovoltaic panel fastening device 10.

As illustrated in FIGS. 1 and 2, in some embodiments, the side plate 110 has an opening 112, and the side plate 120 has an opening 122. A fixing component 360 can pass through one or both of the opening 112 and the opening 122, to fix the photovoltaic panel supporting post 300 into the loading recess 102. For example, the fixing component 360 can be inserted into or bolted into a photovoltaic panel supporting post 300 through the opening 112. In some embodiments, the opening 112 and the opening 122 may be, but not limited to, a U-shaped slot, an enclosed elongate hole, a circular hole, or a threaded hole.

In some embodiments, the bottom plate 130 of the loading pedestal 100 has a centre 132 at a bottom surface. The first supporting plate 210 is connected to the centre 132 of the bottom plate 130 such that the bottom plate 130 and the photovoltaic panel supporting post 300 disposed thereon can be steadily supported by the first supporting plate 210. In some embodiments, the first supporting plate 210 is not only connected to the centre 132 of the bottom plate 130, but also parallel with an extending direction of the side plate 110 and the side plate 120. It should be understood that the centre 132 refers that two parts of the bottom plate 130 disposed respectively on two sides of the centre 132 are symmetric.

In some embodiments, a centroidal axis 214 of the first supporting plate 210 and a centroidal axis 302 of the photovoltaic panel supporting post 300 are overlapped or parallel with each other. Thus, a mean force applied on the bottom plate 130 by the photovoltaic panel supporting post 300 is transmitted into the first supporting plate 210 along the centroidal axis 214 of the first supporting plate 210, such that the loading pedestal 100 and the photovoltaic panel supporting post 300 are more steadily supported by the first supporting plate 210. It should be understood that the centroidal axis 214 refers to an axis longitudinally passing through the cross-sectional centroid of the first supporting plate 210. Similarly, the centroidal axis 302 refers to an axis longitudinally passing through the centroid of the photovoltaic panel supporting post 300.

In some embodiments, the first supporting plate 210 is separated from the second supporting plate 220 with a distance D. The distance D is decreased as toward loading pedestal 100. In other words, the distance D between the first supporting plate 210 and the second supporting plate 220 is increased as far from the loading pedestal 100, in order that these supporting plates can steadily stand on the building.

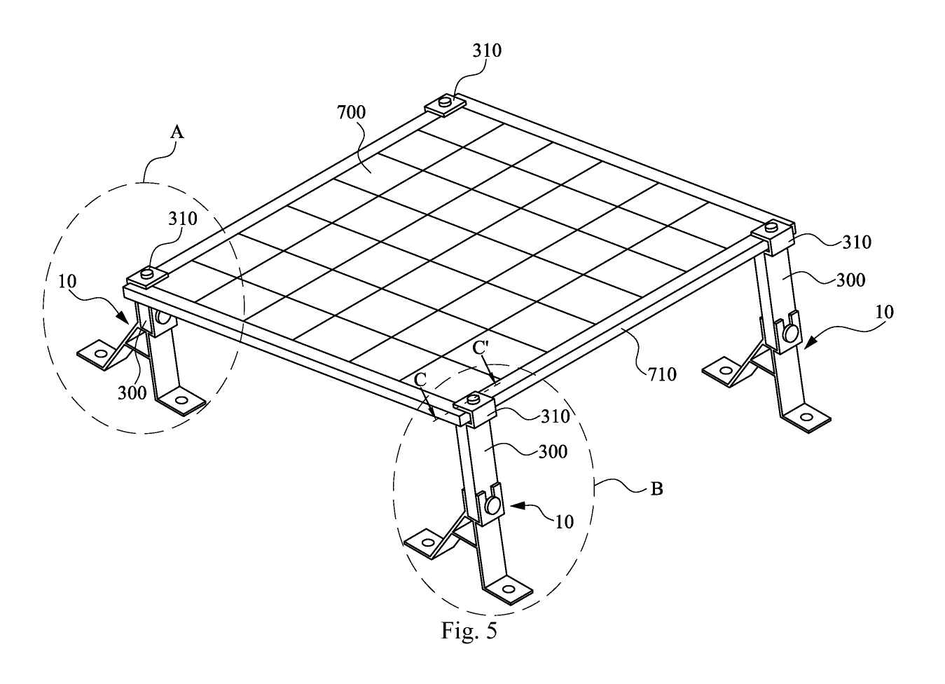

FIG. 3 is a front view of the photovoltaic panel fastening device 10 of FIG. 2. As illustrated in FIG. 3, in some embodiments, the first supporting plate 210 is connected to the bottom plate 130 of the loading pedestal 100 in a tilt manner. Specifically, a first angle α included between the first supporting plate 210 and the bottom plate 130 is toward the second supporting plate 220, where 90°<α<180°. In addition, a second angle β included between the second supporting plate 220 and the bottom plate 130 is toward the first supporting plate 210, where 90°<β<180°. In this embodiment, the first angle α is not equal to the second angle β, and, the first angle α is, but not limited to, less than the second angle β. In other words, the first supporting plate 210 and the second supporting plate 220 are respectively extended outwardly from the bottom of the bottom plate 130. Therefore, when the bottom plate 130 is subjected to a downward force, the first supporting plate 210 and the second supporting plate 220 can disperse the force outwardly.

In some embodiments, the side plate 110 and the side plate 120 are connected to the upper side of the bottom plate 130 in a tilt manner. These side plates may also be parallel with an extending direction of the first supporting plate 210.

In some embodiments, the photovoltaic panel fastening device 10 may also include a structure reinforcement part 500 which connects the first supporting plate 210 with the second supporting plate 220 for protecting the first supporting plate 210 and the second supporting plate 220 from deformation.

In some embodiments, the bottom plate 130, the first supporting plate 210, the second supporting plate 220 and the structure reinforcement part 500 may enclose to construct a hollow tube 510. Specifically, the structure reinforcement part 500 is a plate which serves as a part of the hollow tube 510. Since the bottom plate 130, the first supporting plate 210, the structure reinforcement part 500, and the second supporting plate 220 are sequentially connected without an interval, the structural strength can be further improved.

In some embodiments, the hollow tube 510 is a trapezoidal tube. Specifically, the bottom plate 130 and the structure reinforcement part 500 are parallel with each other, and respectively act as the top and the base of the trapezoidal tube. The first supporting plate 210 and the second supporting plate 220 are inclined and connect the bottom plate 130 and the structure reinforcement part 500. These two supporting plates may also respectively act as two asymmetric sides of the trapezoidal tube, so that a section of the hollow tube 510 presents as an asymmetric trapezium. Specifically, the first angle α is not equal to the second angle β, so that the section of the hollow tube 510 presents as an asymmetric trapezium. Through this trapezoidal design, when the bottom plate 130 is subjected to a heavy force, the first supporting plate 210 and the second supporting plate 220 can protect the bottom plate 130 from downward deformation, and the structure reinforcement part 500 can protect the first supporting plate 210 and the second supporting plate 220 from outward deformation.

In some embodiments, the loading pedestal 100, the first supporting plate 210, the second supporting plate 220, and the structure reinforcement part 500 are integrally formed. In other words, there is no locking or connecting piece among the loading pedestal 100, the first supporting plate 210, the second supporting plate 220, and the structure reinforcement part 500. Thus, the structural strength of the hollow tube 510 can be further enhanced.

In some embodiments, the photovoltaic panel fastening device 10 may further include a first fixed foot 410 and a second fixed foot 420. The first supporting plate 210 has an end 212 which is far from the loading pedestal 100. The first fixed foot 410 is connected to the end 212 of the first supporting plate 210. Similarly, the second supporting plate 220 has an end 222 which is far from the loading pedestal 100. The second fixed foot 420 is connected to the end 222 of the second supporting plate 220. A third angle γ included between the first fixed foot 410 and the first supporting plate 210 is opposite to the second supporting plate 220, where 90°<γ<180°. A forth angle θ included between the second fixed foot 420 and the second supporting plate 220 is opposite to the first supporting plate 210, where 90°<θ<180°. Thus, the first fixed foot 410 and the second fixed foot 420 can outwardly disperse a force subjected by the first supporting plate 210 and the second supporting plate 220 to avoid the deformation of the first supporting plate 210 and the second supporting plate 220. In this embodiment, the bottom plate 130 may also be parallel with the first fixed foot 410 and the second fixed foot 420. As a result, the first angle α is equal to the third angle γ, and the second angle β is equal to the forth angle θ, while the third angle γ is, but not limited to, not equal to the forth angle θ.

In some embodiments, the first fixed foot 410 and the second fixed foot 420 are coplanar in order that the both feet can be stably placed on a building or flat ground to protect the photovoltaic panel fastening device 10 from inclining and falling.

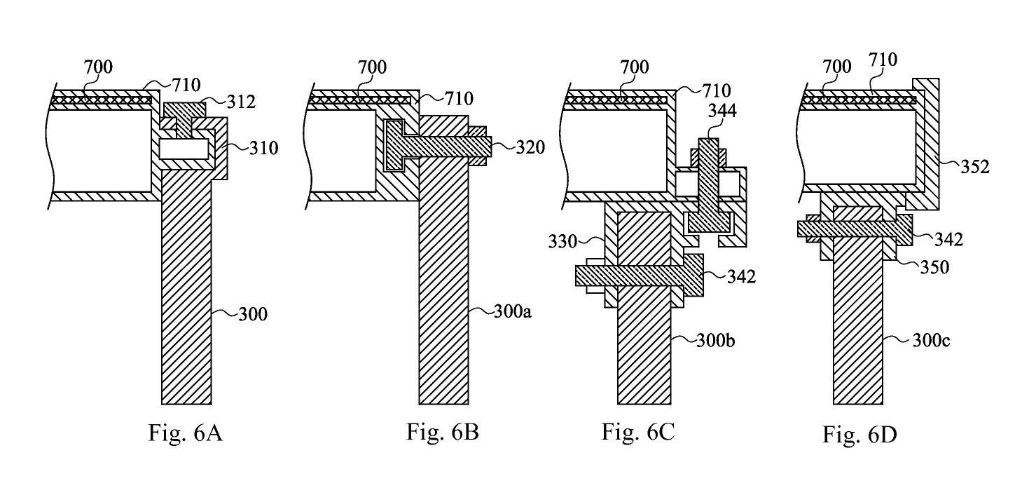

FIG. 4 is a cross-sectional view of the photovoltaic panel fastening device 10 of FIG. 3 fixed on an architectural structure 520. As illustrated in FIG. 4, in some embodiments, the photovoltaic panel fastening device 10 may also include a first fastener 610 and a second fastener 620. The first fastener 610 fixes the first fixed foot 410 on the architectural structure 520. The second fastener 620 fixes the second fixed foot 420 on the architectural structure 520. Thus, the photovoltaic panel fastening device 10 can steadily stand on the architectural structure 520.

Specifically, the first fixed foot 410 may have a first fixing hole 412. The first fastener 610 may insert into the architectural structure 520 via the first fixing hole 412. Thus, the first fixed foot 410 can be fixed on the architectural structure 520. Similarly, the second fixed foot 420 may have a second fixing hole 422. The second fastener 620 may insert into the architectural structure 520 via the second fixing hole 422. Thus, the second fixed foot 420 is fixed on the architectural structure 520. In some embodiments, the first fastener 610 and the second fastener 620 may be, but not limited to, screws or bolts. The first fixing hole 412 and the second fixing hole 422 may be, but not limited to, threaded holes corresponding to the first fastener 610 and the second fastener 620. In some embodiments, the architectural structure 520 may be, but not limited to, a cement base. In addition, plural recesses 522 and 524 may be formed in the architectural structure 520 for containing the first fastener 610 and the second fastener 620.

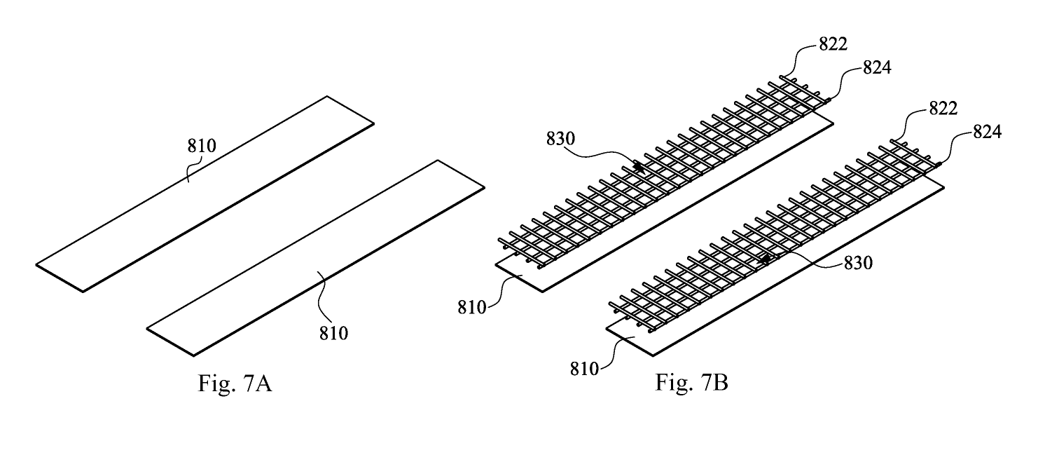

FIG. 5 is a perspective view of a photovoltaic panel system in accordance with an embodiment of the present invention. As illustrated in FIG. 5, in this embodiment, the photovoltaic panel system may include a photovoltaic panel 700, a frame 710, plural photovoltaic panel fastening devices 10, and plural photovoltaic panel supporting posts 300. The frame 710 is used to contain the photovoltaic panel 700. The photovoltaic panel supporting post 300 is fixed on the photovoltaic panel fastening device 10, while the frame 700 is fixed on the photovoltaic panel supporting post 300. Specifically, the frame 710 surrounds the photovoltaic panel 700 and fixes the photovoltaic panel 700 therein. The photovoltaic panel supporting post 300 has a clamping part 310. The clamping part 310 clamps the frame 710. Several clamping parts 310 of plural photovoltaic panel supporting posts 300 can clamp different corners of the frame 710 to fix the frame 710. These photovoltaic panel supporting posts 300 may have different heights for adjusting the angle and height of the photovoltaic panel 700 relative to the ground or the architectural structure. The structure of the photovoltaic panel fastening device 10 thereof is as described above and will not be repeated here.

Basing on the simulation data, a yield stress of the photovoltaic panel fastening device 10 provided in the present invention is about 276 MPa. When the photovoltaic panel system of this embodiment is subjected to a pressure of 5400 Pa, the maximum stress subjected by the photovoltaic panel fastening device 10 positioned in the front area A is 125.6 MPa, and the maximum stress subjected by the photovoltaic panel fastening device 10 positioned in the rear area B is 62.1 MPa. Both of these stresses are less than the yield stress of the photovoltaic panel fastening device 10 so that these fastening devices will not be permanently deformed. Thus, it can be verified that even if the photovoltaic panel system is located in a frigid-zone region and subjected to a snow pressure up to 5400 Pa, a high structural strength of the photovoltaic panel fastening device 10 can protect the system from the permanent deformation.

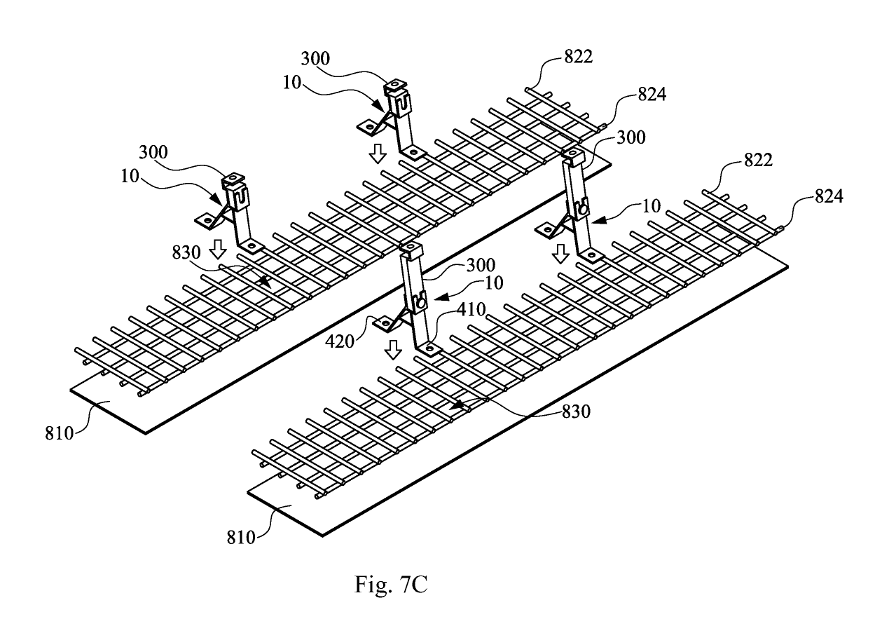

FIG. 6A is a cross-sectional view cut along a line C-C′ in FIG. 5. As illustrated in this figure, in this embodiment, the clamping part 310 of the photovoltaic panel supporting post 300 clamps the frame 710, and a fastener 312 is further used to fix the clamping part 310 and the frame 710 together.

FIG. 6B is a local cross-sectional view of the photovoltaic panel system in accordance with a variation of the present invention. A main difference between the embodiments shown in FIG. 6B and in FIG. 6A is that a photovoltaic panel supporting post 300a of this embodiment does not include the clamping part 310, and a fastener 320 is adopted to fix the photovoltaic panel supporting post 300a and the frame 710 together.

FIG. 6C is a local cross-sectional view of the photovoltaic panel system in accordance with another variation of the present invention. A main difference between the embodiments shown in FIG. 6C and FIG. 6B is that a photovoltaic panel supporting post 300b of this embodiment is connected to a frame 710 by a joint piece 330. Specifically, the joint piece 330 is fixed on the photovoltaic panel supporting post 300b by a fastener 342, and connected to the frame 710 by another fastener 344.

FIG. 6D is a local cross-sectional view of a photovoltaic panel system in accordance with yet another variation of the present invention. A main difference between the embodiments shown in FIG. 6D and FIG. 6C is that a joint piece 350 of this embodiment has a clamping part 352 which can clamp and fix the frame 710. In addition, the joint piece 350 is fixed on a photovoltaic panel supporting post 300c by a fastener 342.

It should be understood that different variations of photovoltaic panel supporting posts 300-300c in FIGS. 6A-6D are only used for exemplary purposes rather than limiting the present invention. In practice, any structure that can fix the frame 710 (regardless of in clamping, locking, or other fixing ways) can be the selection and will be applied on the photovoltaic panel supporting post 300.

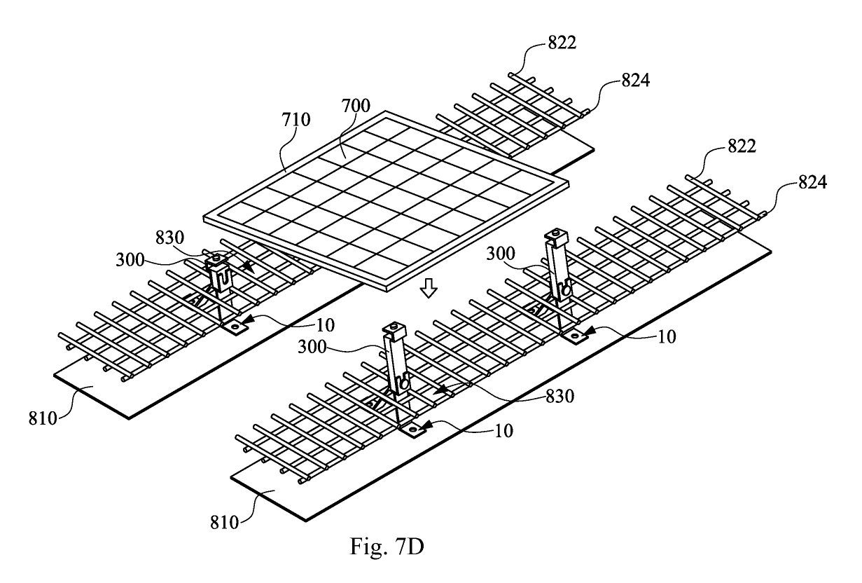

FIGS. 7A-7E are perspective views of steps of installing a photovoltaic panel system in accordance with an embodiment of the present invention. As illustrated in FIG. 7A, in this embodiment, at least one template 810 may be provided first. For example, the template 810 may be set above a building roof.

As illustrated in FIG. 7B, a plurality of limit grids 830 may be set on the template 810. Specifically, multiple transversal limit strips 822 and multiple longitudinal limit strips 824 may be arranged on the template 810. These transversal limit strips 822 and longitudinal limit strips 824 intersect with each other to construct a plurality of limit grids 830. These transversal limit strips 822 and longitudinal limit strips 824 described above may be, but not limited to, steel strips.

As illustrated in FIG. 7C, the photovoltaic panel fastening device 10 may be placed within the limit grids 830. Since the photovoltaic panel fastening device 10 has the first fixed foot 410 and the second fixed foot 420 coplanar to each other, the photovoltaic panel fastening device 10 can be stably placed on the template 810 underneath the limit grids 830.

As illustrated in FIG. 7D, the photovoltaic panel 700 may be fixed on the photovoltaic panel fastening device 10 and further fixed on the template 810 or the building. Specifically, the photovoltaic panel 700 is contained by the frame 710. The photovoltaic panel fastening device 10 can fix the frame 710, which is used to fix the photovoltaic panel 700, through the photovoltaic panel supporting post 300. The fixing means for the photovoltaic panel fastening device 10 and the frame 710 can be referred to FIGS. 6A-6D and the related description above, and will not be repeated here.

As illustrated in FIG. 7E, an uncoagulated construction material 850 may flow into the limit grids 830 to cover the first fixed foot 410 and the second fixed foot 420 of the photovoltaic panel fastening device 10. Specifically, since the construction material 850 is uncoagulated, it flows into the limit grids 830 and spread on the template 810 through a conduit 840. When a certain amount of construction material 850 flows into the limit grids 830, this construction material 850 may stack on the template 810 and then covers the first fixed foot 410 and the second fixed foot 420. After the construction material 850 is coagulated, the first fixed foot 410 and the second fixed foot 420 can be steadily buried in the construction material 850. In some embodiments, the construction material 850 may be, but not limited to, concrete.

Since a conventional L-shaped support only has a single pillar, this kind of support is prone to be swept down by the flow of the uncoagulated construction material 850 when it is directly placed into the limit grids 830. Therefore, traditional process of installing the photovoltaic panel 700 are all as follows: the construction material 850 is entirely coagulated firstly, and then the L-shaped support is installed above the surface of the coagulated construction material 850, and finally the photovoltaic panel 700 is installed. However, since a construction material 850 needs average four to five days to convert from an uncoagulated state to a coagulated state, it quite wastes lots of time before the L-shaped support and the photovoltaic panel 700 are installed. However, since the first fixed foot 410 and the second fixed foot 420 of the photovoltaic panel fastening device 10 provided in the present invention may be flatwise placed on the template 810, the system is not prone to be swept down by the flow of the construction material 850. Therefore, the photovoltaic panel fastening device 10 may be placed on the template 810 before the construction material 850 flow into. It significantly reduces the time wasted on waiting for coagulation of the construction material 850.

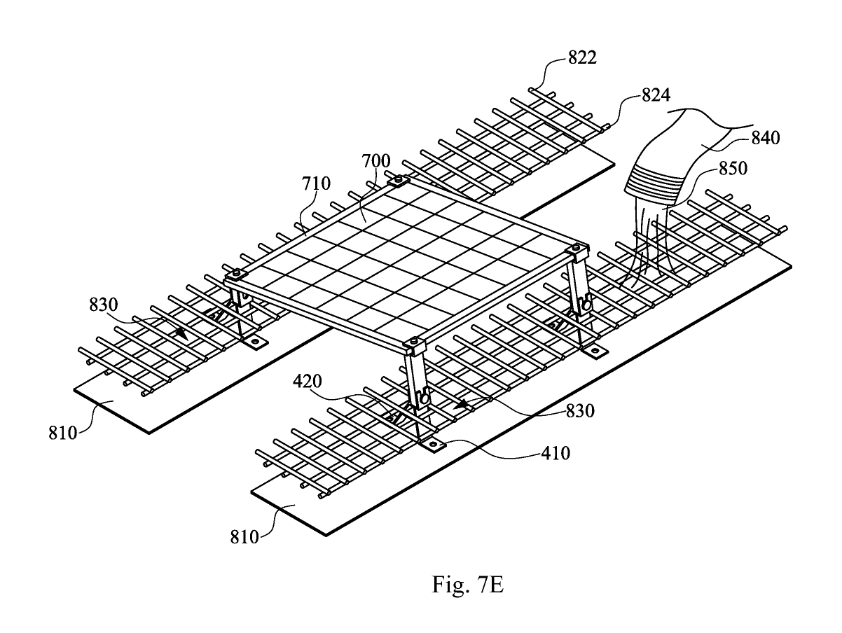

FIG. 8 is a side view of the photovoltaic panel fastening device 10 on the template 810 in accordance with an embodiment of the present invention. As illustrated in FIG. 8, at least one first bolt 910 and at least one second bolt 920 may be firstly placed on the template 810. Next, at least one first nut 930 and at least one second nut 940 may be respectively bolted onto the first bolt 910 and the second bolt 920. Then, the first fixed foot 410 and the second fixed foot 420 of the photovoltaic panel fastening device 10 are respectively hitched on the first bolt 910 and the second bolt 920. In addition, the first fixed foot 410 and the second fixed foot 420 may be respectively abutted against the top faces of the first nut 930 and the second nut 940. Subsequently, the first nut 930 and the second nut 940 may be screwed to adjust the distances from the first fixed foot 410 or the second fixed foot 420 to the template 810. The first bolt 910 and the second bolt 920 described above are positioned between the two transversal limit strips 822 and the two longitudinal limit strips 824.

The installer may use the method described above to adjust the height of the photovoltaic panel fastening device 10 through the first nut 930 and the second nut 940 to keep different photovoltaic panels 700 (referring to FIG. 7E) staying at the same height before the construction material 850 (referring to FIG. 7E) is introduced. After the construction material 850 is introduced and coagulated, the first nut 930 and the second nut 940 are fixed in position on the first bolt 910 and the second bolt 920, which are not prone to loosen or shift.

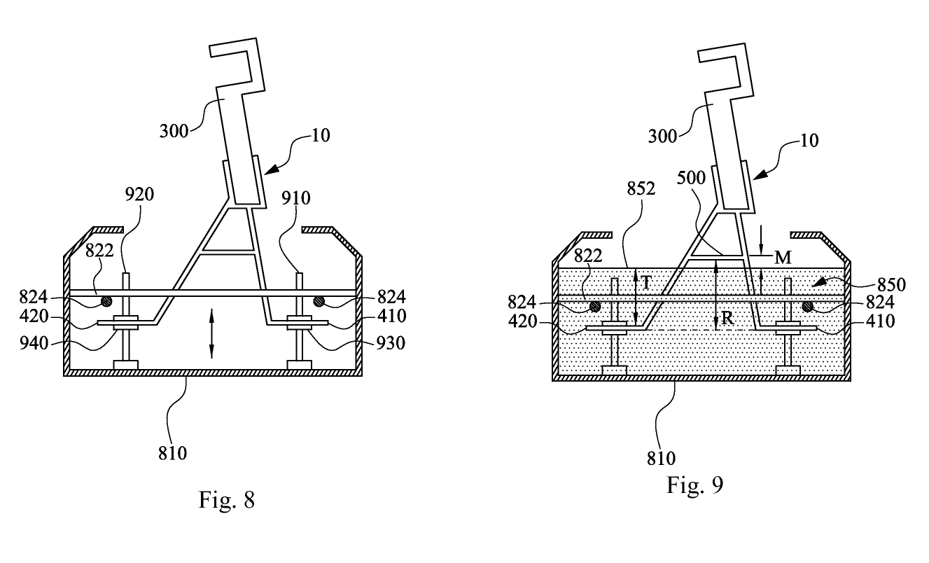

FIG. 9 is a side view of the photovoltaic panel fastening device 10 on the template 810 in accordance with another embodiment of the present invention. As illustrated on FIG. 9, a reference interval R is defined between the first fixed foot 410, or the second fixed foot 420, and the structure reinforcement part 500. The size of this reference interval R is determined by the manufacturer when the photovoltaic panel fastening device 10 is made. Next, a measured interval M is defined between an exposed face 852 of the construction material 850 and the structure reinforcement part 500. The value of measured interval M can be derived from the visual observation or measurement implemented by the installer. Then, the value of the measured interval M is subtracted from the value of the reference interval R to derive the value of a burying depth T of the first fixed foot 410 or the second fixed foot 420 buried under the exposed face 852 of the construction material 850. In other words, the installer can realize the value of the burying depth T of the first fixed foot 410 or the second fixed foot 420 via the gap between the reference interval R and the measured interval M in the condition that the first fixed foot 410 and the second fixed foot 420 are buried in the construction material 850. In another embodiment, when the burying depth T is decided before construction, this value can be marked through the scales on the fastening device 10 or the distance between limit strips and the first fixed foot 410 as well as the second fixed foot 420. Therefore, When the construction material 850 is poured into the template 810, it is easy for the installer to determine when to stop. A tension value of the photovoltaic panel fastening device 10 changes depending on the burying depth T. In these embodiments described above of the present invention, the value of the burying depth T may be derived via the gap between the reference interval R and the measured interval M, which is related to the tension value of the photovoltaic panel fastening device 10. In practice, the reference interval R usually is, but not limited to in the present invention, 5 cm.

Although the present invention has been disclosed with reference to the above embodiments, these embodiments are not intended to limit the present invention. It will be apparent to those skilled in the art that various modifications and variations can be made without departing from the scope or spirit of the present invention. Therefore, the scope of the present invention shall be defined by the appended claims.

What is claimed is:

1. A photovoltaic panel fastening device, comprising:
a loading pedestal, comprising a plurality of side plates and a bottom plate, wherein the side plates are disposed on the bottom plate and respectively connected to two opposite ends of the bottom plate, and thereby constructing a loading recess, and the side plates respectively include an opening;
a first supporting plate connected underneath the bottom plate; and
a second supporting plate connected underneath the bottom plate and connected to one of the side plates.

2. The photovoltaic panel fastening device of claim 1, wherein the first supporting plate is connected to a centre of a bottom surface of the bottom plate.

3. The photovoltaic panel fastening device of claim 1, wherein a distance between the first supporting plate and the second supporting plate is decreased as toward the loading pedestal.

4. The photovoltaic panel fastening device of claim 1, wherein the first supporting plate and the second supporting plate are connected to the bottom plate in a non-perpendicular manner.

5. The photovoltaic panel fastening device of claim 4, wherein the side plates are connected to the upper side of the bottom plate in a non-perpendicular manner.

6. The photovoltaic panel fastening device of claim 4, wherein the side plates are parallel with an extending direction of the first supporting plate.

7. The photovoltaic panel fastening device of claim 1, further comprising:
a structure reinforcement part, connected between the first supporting plate and the second supporting plate.

8. The photovoltaic panel fastening device of claim 7, wherein the bottom plate, the first supporting plate, the second supporting plate, and the structure reinforcement part enclose to construct a hollow tube.

9. The photovoltaic panel fastening device of claim 8, wherein the bottom plate is parallel with the structure reinforcement part.

10. The photovoltaic panel fastening device of claim 8, wherein the hollow tube is a trapezoidal tube.

11. The photovoltaic panel fastening device of claim 10, wherein a first angle is defined between the first supporting plate and the bottom plate, a second angle is defined between the second supporting plate and the bottom plate, and the first angle is not equal to the second angle.

12. The photovoltaic panel fastening device of claim 7, wherein the loading pedestal, the first supporting plate, the second supporting plate and the structure reinforcement part are integrally formed.

13. The photovoltaic panel fastening device of claim 1, further comprising:
a first fixed foot connected to an end of the first supporting plate far from the loading pedestal; and
a second fixed foot connected to an end of the second supporting plate far from the loading pedestal.

14. The photovoltaic panel fastening device of claim 13, wherein the first fixed foot and the second fixed foot are coplanar.

15. The photovoltaic panel fastening device of claim 1, further comprising:
a photovoltaic panel supporting post fixed into the loading recess, wherein a centroidal axis of the first supporting plate and a centroidal axis of the photovoltaic panel supporting post are parallel with each other.

16. A photovoltaic panel system, comprising:
a photovoltaic panel;
a frame containing the photovoltaic panel;
at least one photovoltaic panel supporting post; and
at least one photovoltaic panel fastening device, comprising:
a loading pedestal, comprising a plurality of side plates and a bottom plate, wherein the side plates are disposed on the bottom plate and respectively connected to two opposite ends of the bottom plate, and thereby constructing a loading recess, and the side plates respectively include an opening;
a first supporting plate connected underneath the bottom plate; and
a second supporting plate connected underneath the bottom plate and connected to one of the side plates,
wherein the photovoltaic panel supporting post is fixed on the photovoltaic panel fastening device, and the frame is fixed on the photovoltaic panel supporting post.

17. The photovoltaic panel system of claim 16, wherein the first supporting plate is connected to a centre of a bottom surface of the bottom plate.

18. The photovoltaic panel system of claim 16, wherein a distance between the first supporting plate and the second supporting plate is decreased as toward the loading pedestal.

19. The photovoltaic panel system of claim 16, wherein the first supporting plate and the second supporting plate are connected to the bottom plate in a non-perpendicular manner.

20. The photovoltaic panel system of claim 19, wherein the side plates are connected to the upper side of the bottom plate in a non-perpendicular manner.

21. The photovoltaic panel system of claim 16, wherein the photovoltaic panel fastening device further comprising:
a structure reinforcement part, connected between the first supporting plate and the second supporting plate.

22. The photovoltaic panel system of claim 21, wherein the bottom plate is parallel with the structure reinforcement part.

23. The photovoltaic panel system of claim 16, wherein a first angle is defined between the first supporting plate and the bottom plate, a second angle is defined between the second supporting plate and the bottom plate, and the first angle is not equal to the second angle.

24. The photovoltaic panel system of claim 16, wherein a centroidal axis of the first supporting plate and a centroidal axis of the photovoltaic panel supporting post are parallel with each other.
